(19) United States
(12) Patent Application Publication
(10) Pub. No.: US 2012/0161168 A1
(43) Pub. Date: Jun. 28, 2012

(54) LIGHT EMITTING DEVICE

(76) Inventor: Yu-Nung Shen, Taipei City (TW)

(21) Appl. No.: 13/409,041

(22) Filed: Feb. 29, 2012

Related U.S. Application Data
(62) Division of application No. 12/031,606, filed on Feb. 14, 2008.

(30) Foreign Application Priority Data
Feb. 16, 2007 (TW) 096106351

(51) Int. Cl. H01L 33/60

(52) U.S. Cl. 257/88; 257/E33.072

(57) ABSTRACT

A light emitting device includes: a chip-mounting base formed with a plurality of conductive contacts; a reflector mounted on the chip-mounting base and defining a central hole; a first light emitting chip mounted on the chip-mounting base within the central hole and in electrical contact with respective ones of the conductive contacts for generating light with a first primary wavelength; a second light emitting chip stacked on and in electrical contact with the first light emitting chip for generating light with a second primary wavelength different from the first primary wavelength; and an encapsulant filling the central hole and capable of converting the first and second primary wavelengths into first and second secondary wavelengths, respectively.

### CROSS-REFERENCE TO RELATED APPLICATION

This application is a divisional of U.S. patent application Ser. No. 12/031,606, filed Feb. 14, 2008, which claims priority of Taiwanese application no. 096106351, filed on Feb. 16, 2007.

### BACKGROUND OF THE INVENTION

1. Field of the Invention

This invention relates to a light emitting device, more particularly to a light emitting device having a brightness-enhancing design.

2. Description of the Related Art

Light emitting devices, such as light emitting diodes and laser emitting diodes, have recently been applied to displays and various light sources. Hence, there is a need to enhance the brightness of the light emitting devices.

### SUMMARY OF THE INVENTION

An object of the present invention is to provide a light emitting device that has an improved brightness.

According to one aspect of this invention, a light emitting device comprises: a chip-mounting base having a mounting surface and formed with a plurality of conductive contacts on the mounting surface; a reflector mounted on a periphery of the mounting surface of the chip-mounting base and defining a central hole for exposing the mounting surface of the chip-mounting base; a first light emitting chip mounted on the mounting surface of the chip-mounting base within the central hole in the reflector and in electrical contact with respective ones of the conductive contacts for generating light with a first primary wavelength; a second light emitting chip stacked on and in electrical contact with the first light emitting chip for generating light with a second primary wavelength different from the first primary wavelength; and an encapsulant filling the central hole in the reflector to enclose the first and second light emitting chips and capable of converting the first and second primary wavelengths into first and second secondary wavelengths, respectively.

According to another aspect of this invention, a light emitting device comprises: a chip-mounting base having a mounting surface and formed with a plurality of conductive contacts on the mounting surface; a reflector mounted on a periphery of the mounting surface of the chip-mounting base and defining a central hole for exposing the mounting surface of the chip-mounting base; a first light emitting chip mounted on the mounting surface of the chip-mounting base within the central hole in the reflector and in electrical contact with respective ones of the conductive contacts for generating light with a first primary wavelength; a second light emitting chip mounted on the mounting surface of the chip-mounting base within the central hole in the reflector, juxtaposed with the first light emitting chip, and in electrical contact with respective ones of the conductive contacts for generating light with a second primary wavelength different from the first primary wavelength; and an encapsulant filling the central hole in the reflector to enclose the first and second light emitting chips and capable of converting the first and second primary wavelengths into first and second secondary wavelengths, respectively.

According to yet another aspect of this invention, alight emitting device comprises: a chip-mounting base having a mounting surface; a reflector mounted on a periphery of the mounting surface of the chip-mounting base and defining a central hole for exposing the mounting surface of the chip-mounting base; a light emitting chip disposed outwardly of the chip-mounting base and the ref lector for generating light with a primary wavelength; an optical fiber transmission line connected to the light emitting chip and extending therefrom into the central hole in the reflector; and an encapsulant filling the central hole in the reflector to enclose an end portion of the optical fiber transmission line and capable of converting the primary wavelength into a secondary wavelength.

According to still another aspect of this invention, alight emitting device comprises: a chip-mounting base having a mounting surface and formed with a plurality of conductive contacts on the mounting surface; a reflector mounted on a periphery of the mounting surface of the chip-mounting base and defining a central hole for exposing the mounting surface of the chip-mounting base; a first light emitting chip mounted on the mounting surface of the chip-mounting base within the central hole in the reflector and in electrical contact with respective ones of the conductive contacts for generating light with a first primary wavelength; an encapsulant filling the central hole in the reflector to enclose the first light emitting chip; a second light emitting chip; and a transparent base disposed outwardly of the chip-mounting base and the reflector and having a mounting surface facing and aligned with the mounting surface of the chip-mounting base in a transverse direction relative to the mounting surface of the chip-mounting base. The second light emitting chip is mounted on the mounting surface of the transparent base for generating light with a second primary wavelength. The mounting surface of the transparent base is formed with a reflective protrusion protruding therefrom for receiving and reflecting the light from the second light emitting chip to the encapsulant.

According to a further aspect of this invention, a light emitting device comprises a light emitting chip including a sapphire substrate, a first semiconductor layer formed on the sapphire substrate, and a second semiconductor layer formed on the first semiconductor layer for generating light with a primary wavelength. The sapphire substrate has a back surface opposite to the first semiconductor layer and is formed with a plurality of recesses indented inwardly from the back surface. Each of the recesses in the sapphire substrate is filled with a wavelength-converting material for converting the primary wavelength into a secondary wavelength.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic partly sectional view of the first preferred embodiment of a light emitting device according to this invention;

FIG. 2 is a schematic view to illustrate a configuration of a light source formed of a plurality of the light emitting devices of the first preferred embodiments;

FIG. 3 is a schematic partly sectional view of the second preferred embodiment of the light emitting device according to this invention;

FIG. 4 is a schematic partly sectional view of the third preferred embodiment of the light emitting device according to this invention;

FIG. 5 is a schematic partly sectional view of the fourth preferred embodiment of the light emitting device according to this invention;

FIG. 6 is a schematic view of the fifth preferred embodiment of the light emitting device according to this invention;

FIG. 7 is a schematic partly sectional view of the sixth preferred embodiment of the light emitting device according to this invention;

FIG. 8 is a schematic view of the seventh preferred embodiment of the light emitting device according to this invention;

FIG. 9 is a schematic partly sectional view of the eighth preferred embodiment of the light emitting device according to this invention;

FIG. 10 is a schematic partly sectional view of the ninth preferred embodiment of the light emitting device according to this invention; and

FIG. 11 is a schematic partly sectional view of the tenth preferred embodiment of the light emitting device according to this invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

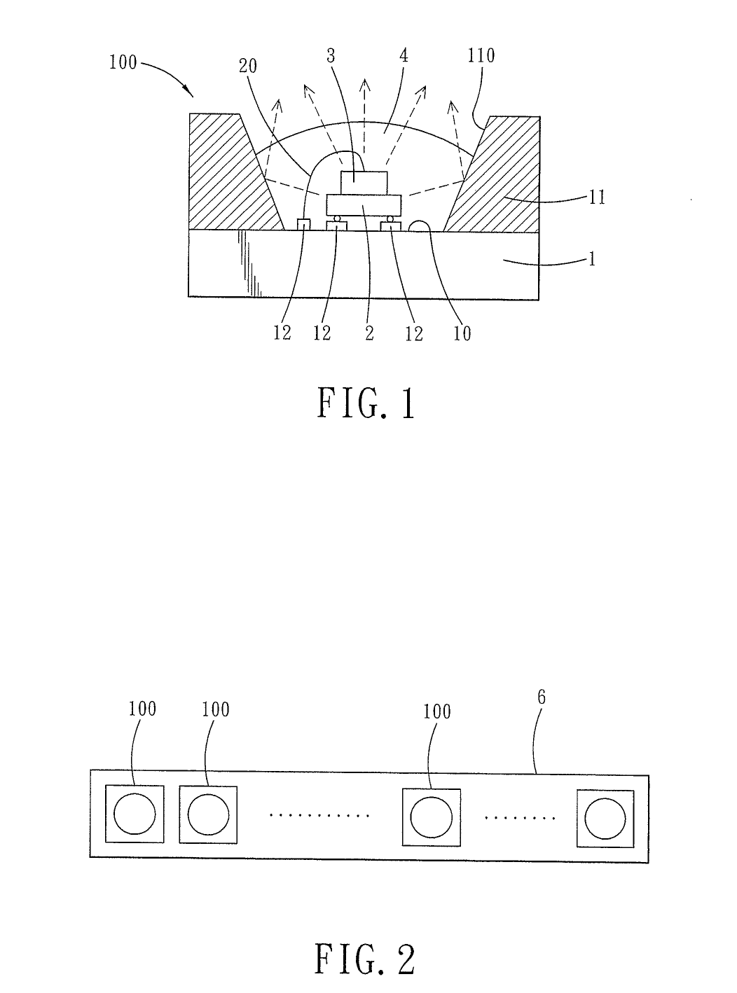

FIG. 1 illustrates the first preferred embodiment of a light emitting device 100 according to the present invention. The light emitting device 100 includes: a chip-mounting base 1 having a mounting surface 10 and formed with a plurality of conductive contacts 12 on the mounting surface 10; a reflector 11 mounted on a periphery of the mounting surface 10 of the chip-mounting base 1 and defining a central hole 110 for exposing the mounting surface 10 of the chip-mounting base 1; a first light emitting chip 2 mounted on the mounting surface 10 of the chip-mounting base 1 within the central hole 110 in the reflector 11 and in electrical contact with respective ones of the conductive contacts 12 for generating light with a first primary wavelength; a second light emitting chip 3 stacked on, in electrical contact with the first light emitting chip 2 through electrode contacts (not shown) formed thereon, and further in electrical contact with a respective one of the conductive contacts 12 through a bonding wire 20 for generating light with a second primary wavelength different from the first primary wavelength; and an encapsulant 4 filling the central hole 110 in the reflector 11 to enclose the first and second light emitting chips 2, 3 and containing first and second wavelength-converting materials so as to be capable of converting the first and second primary wavelengths into first and second secondary wavelengths, respectively.

In this embodiment, the first light emitting chip 2 is a light emitting diode, and the second light emitting chip 3 is a laser diode. Preferably, the chip-mounting base 1 is made from a material with a high thermal conductivity.

Preferably, each of the first and second wavelength-converting materials of the encapsulant 4 contains a respective one of color phosphor materials.

FIG. 2 illustrates a light source formed of a plurality of the light emitting devices 100 of FIG. 1 for application to a backlight of a display or a lamp. The light emitting devices 100 are mounted on an elongate carrier 6.

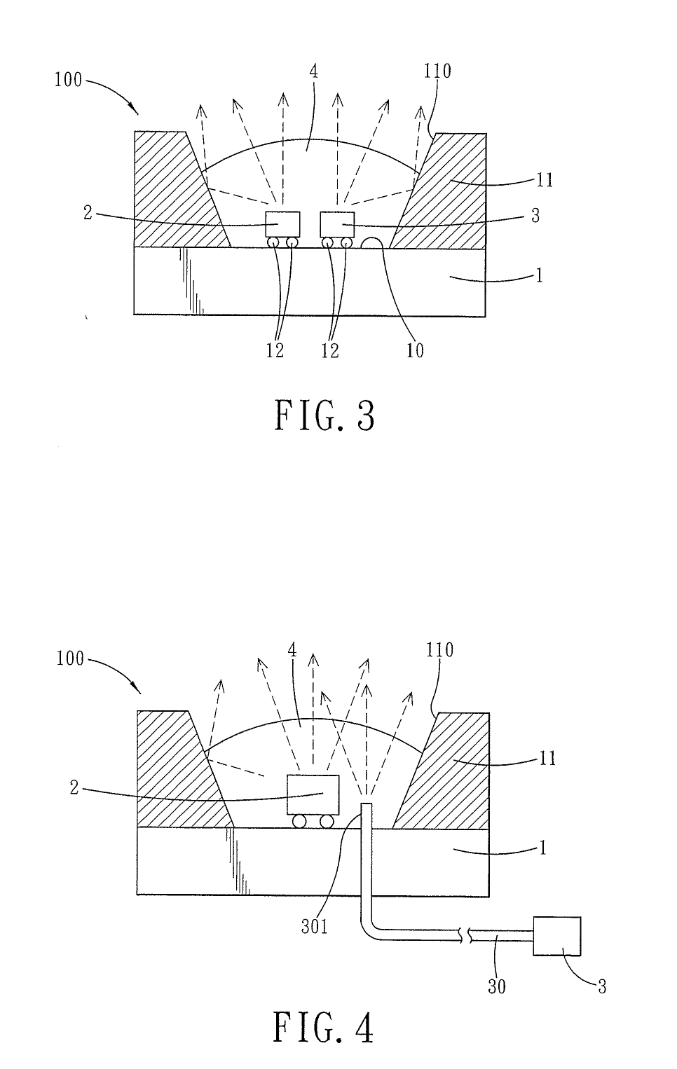

FIG. 3 illustrates the second preferred embodiment of the light emitting device 100 according to the present invention. The second preferred embodiment differs from the previous embodiment in that the second light emitting chip 3 is mounted on the mounting surface 10 of the chip-mounting base 1 within the central hole 110 in the reflector 11, is juxtaposed with the first light emitting chip 2, and is in electrical contact with respective ones of the conductive contacts 12.

FIG. 4 illustrates the third preferred embodiment of the light emitting device 100 according to the present invention. The third preferred embodiment differs from the previous embodiments in that the second light emitting chip 3 is disposed outwardly of the chip-mounting base 1 and the reflector 11 and that the light emitting device 100 further includes an optical fiber transmission line 30 connected to the second light emitting chip 3 and extending therefrom into the central hole 110 in the reflector 11. The encapsulant 4 encloses an end portion 301 of the optical fiber transmission line 30. The optical fiber transmission line 30 may contains a phosphor material for emitting light therethrough.

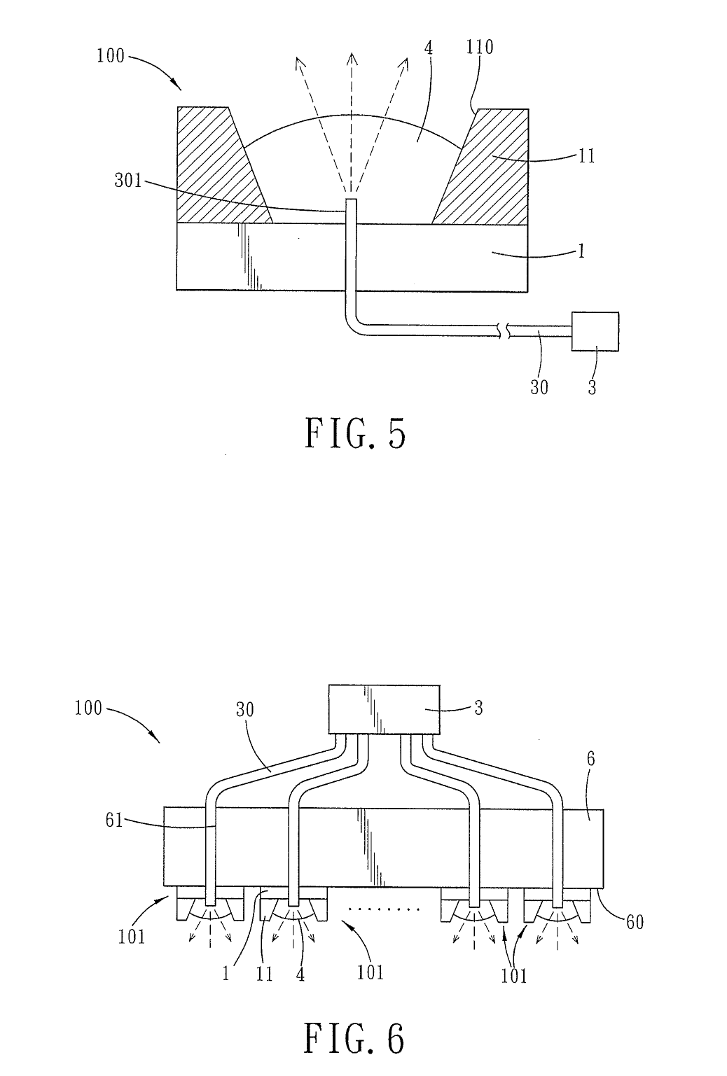

FIG. 5 illustrates the fourth preferred embodiment of the light emitting device 100 according to the present invention. The fourth preferred embodiment differs from third preferred embodiment in that the first light emitting chip 2 is dispensed with.

FIG. 6 illustrates the fifth preferred embodiment of the light emitting device 100 according to the present invention. The fifth preferred embodiment differs from fourth preferred embodiment in that a plurality of light emitting units 101, each including an assembly of the chip-mounting base 1, the reflector 11 and the encapsulant 4, are mounted on a mounting surface 60 of a carrier 6 and that a plurality of optical fiber transmission lines 30 are connected to and extend from the second light emitting chip 3 through a respective one of holes 61 in the carrier 6 and into the encapsulant 4 of each of the light emitting units 101.

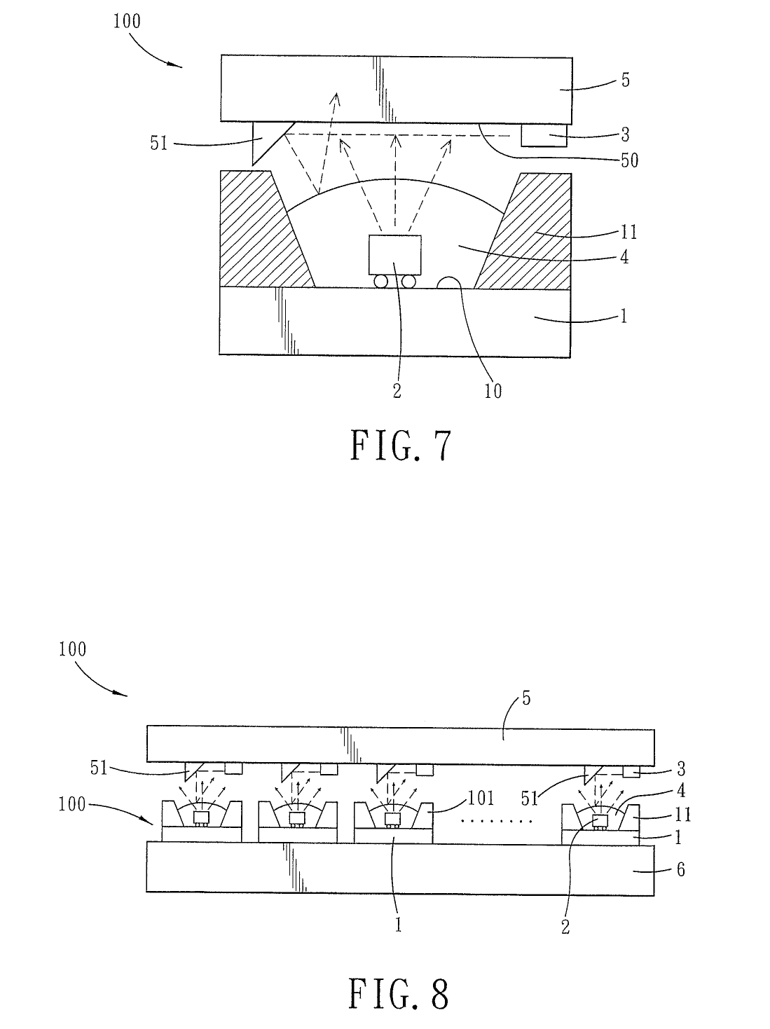

FIG. 7 illustrates the sixth preferred embodiment of the light emitting device 100 according to the present invention. The sixth preferred embodiment differs from the first preferred embodiment in that the light emitting device 100 further includes a transparent base 5 disposed outwardly of the chip-mounting base 1 and the reflector 11 and having a mounting surface 50 facing and aligned with the mounting surface 10 of the chip-mounting base 1 in a transverse direction relative to the mounting surface 10 of the chip-mounting base 1, that the second light emitting chip 3 is mounted on the mounting surface 50 of the transparent base 5, and that the mounting surface 50 of the transparent base 5 is formed with a reflective protrusion 51 protruding therefrom for receiving and reflecting the light from the second light emitting chip 3 to the encapsulant 4.

FIG. 8 illustrates the seventh preferred embodiment of the light emitting device 100 according to the present invention. The seventh preferred embodiment differs from the sixth preferred embodiment in that a plurality of light emitting units 101, each including an assembly of the chip-mounting base 1, the reflector 11, the first light emitting chip 2 and the encapsulant 4, are mounted on a carrier 6 and that a plurality of the second light emitting chips 3 and a plurality of the reflective protrusions 51 are mounted on the transparent base 5. Each reflective protrusion 51 reflects light from a respective one of the second light emitting chips 3 to the encapsulant 4 of a respective one of the light emitting units 101.

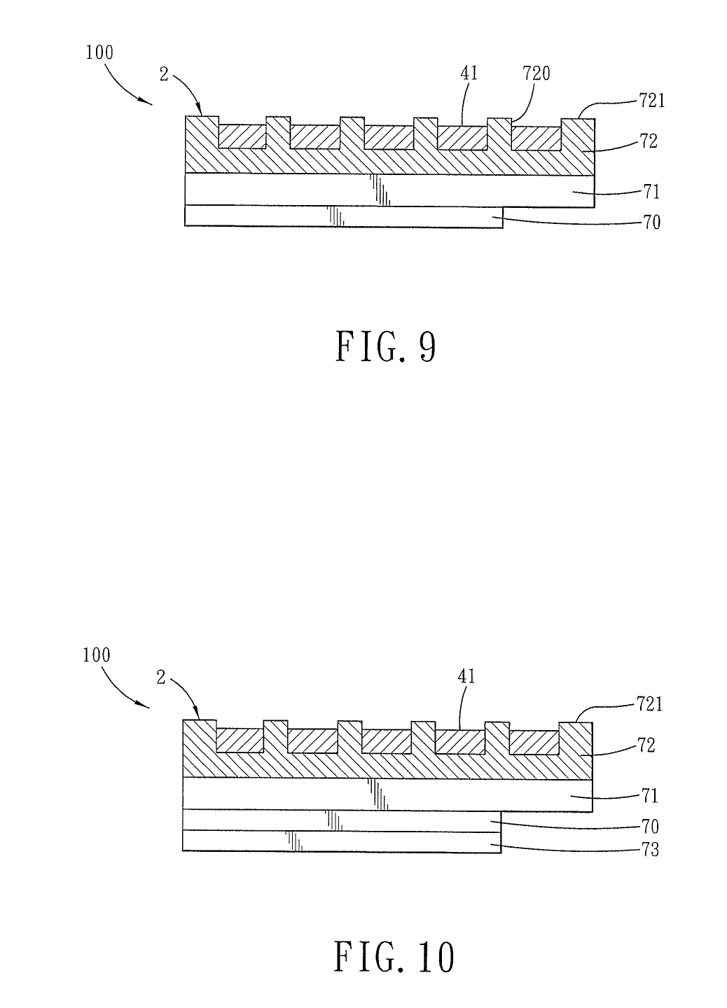

FIG. 9 illustrates the eighth preferred embodiment of the light emitting device 100 according to this invention. The light emitting device 100 of this embodiment includes a first light emitting chip 2 including a sapphire substrate 72, a first semiconductor layer 71 formed on the sapphire substrate 72, and a second semiconductor layer 70 formed on the first semiconductor layer 71 for generating light with a primary wavelength. The sapphire substrate 72 has a back surface 721 opposite to the first semiconductor layer 71 and is formed with a plurality of recesses 720 indented inwardly from the back surface 721. Each of the recesses 720 in the sapphire substrate 72 is filled with a wavelength-converting material 41 for converting the primary wavelength into a secondary wavelength.

In this embodiment, the wavelength-converting material 41 contains one of color phosphor materials and a luminance-enhancing material selected from one of CrTiO₂ and CrO₂ so as to enhance the brightness of the light emitting device 100.

The recesses 720 in the sapphire substrate 72 have a size in the order of microns, and preferably less than 10 μm.

Preferably, the first semiconductor layer 71 is made from a p-type semiconductor material, and the second semiconductor layer 70 is made from an n-type semiconductor material.

A transparent conductive layer (not shown) of indium tin oxide may be formed on the sapphire substrate 72 for enhancing heat dissipation of the light emitting device 100. In addition, a color-shifting film (not shown) having a layer thickness of about 500 angstroms may be formed on the sapphire substrate 72 for achieving a desired blue shift.

FIG. 10 illustrates the ninth preferred embodiment of the light emitting device 100 according to this invention. The ninth preferred embodiment differs from the eighth preferred embodiment in that the first light emitting chip 2 further includes a light reflecting layer formed on the second semiconductor layer 70 and disposed opposite to the first semiconductor layer 71.

The light reflecting layer 73 may be formed with a plurality of micro-recesses (not shown) for enhancing light extraction of the light emitting device 100.

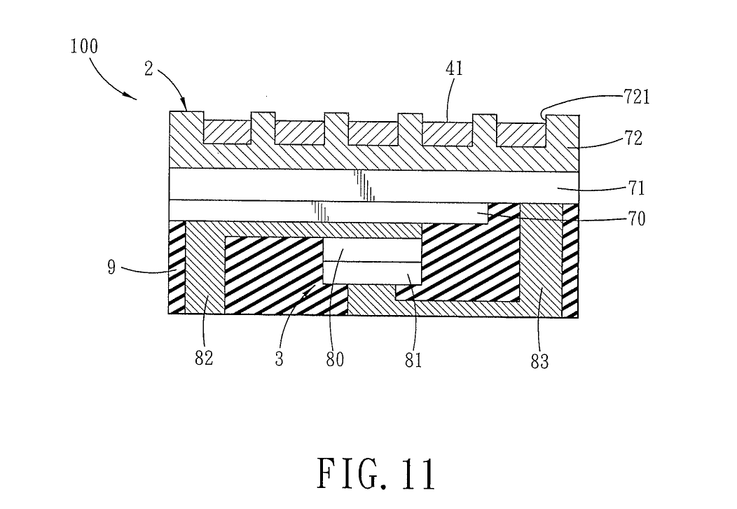

FIG. 11 illustrates the tenth preferred embodiment of the light emitting device 100 according to this invention. The tenth preferred embodiment differs from the eighth preferred embodiment in that the light emitting device 100 further includes a first conductive connecting body 82 formed on the second semiconductor layer 70 of the first light emitting chip 2; a second light emitting chip 3 including a first semiconductor layer 80 formed on the conductive connecting layer 82 and a second semiconductor layer 81 formed on the first semiconductor layer 80 of the second light emitting chip 3 for generating light with a second primary wavelength different from the first primary wavelength; and a second conductive connecting body 83 interconnecting and in electrical contact with the second semiconductor layer 81 of the second emitting chip 3 and the first semiconductor layer 71 of the first emitting chip 2. A sealing material 9 is formed on the second semiconductor layer 70 and a portion of the first semiconductor layer 71 that is exposed from the second semiconductor layer 70 for enclosing the second light emitting chip 3 and the first and second conductive connecting bodies 82, 83.

In this embodiment, the wavelength-converting material 41 in the recesses 720 in the sapphire substrate 72 contains respective ones of color phosphor materials for converting the first and second primary wavelengths into first and second secondary wavelengths, respectively.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A light emitting device comprising:
a chip-mounting base having a mounting surface;
a reflector mounted on a periphery of said mounting surface of said chip-mounting base and defining a central hole for exposing said mounting surface of said chip-mounting base;
one light emitting chip disposed outwardly of said chip-mounting base and said reflector for generating light with a primary wavelength;
an optical fiber transmission line connected to said one light emitting chip and extending therefrom into said central hole in said reflector; and
an encapsulant filling said central hole in said reflector to enclose an end portion of said optical fiber transmission line and capable of converting the primary wavelength into a secondary wavelength.

2. The light emitting device of claim 1, further comprising another light emitting chip mounted on said mounting surface of said chip-mounting base within said central hole in said reflector and enclosed by said encapsulant for generating light with another primary wavelength, said chip-mounting base being formed with a plurality of conductive contacts on said mounting surface, said another light emitting chip being in electrical contact with respective ones of said conductive contacts.

3. The light emitting device of claim 2, wherein said encapsulant is further capable of converting said another primary wavelength into another secondary wavelength.

4. The light emitting device of claim 3, wherein said encapsulant contains at least one color phosphor material.
